(19) United States
(12) Patent Application Publication
(10) Pub. No.: US 2002/0139971 A1
(43) Pub. Date: Oct. 3, 2002

(54) Semiconductor device and method for fabricating same

(75) Inventor: Tsuyoshi Eda, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/112,189

(22) Filed: Mar. 29, 2002

(30) Foreign Application Priority Data
Mar. 29, 2001 (JP) 2001-097185

(51) Int. Cl. H01L 29/06

(52) U.S. Cl. 257/22

(57) ABSTRACT

The first GaAs layer and a FET gate electrode are formed on the top surface of an epitaxial substrate. An AlGaAs layer, the second GaAs layer and the first diode electrode are successively formed on the top surface of the first GaAs layer and near the left end thereof. A diode/FET electrode is formed on the top surface of the first GaAs layer and between the first diode electrode and the FET gate electrode. The diode/FET electrode serves as the second diode electrode in combination with the first diode electrode, and as a source or drain electrode in combination with the FET gate electrode. The first diode electrode is formed by evaporation, and the FET gate electrode is formed by spattering. Since the physical property of the first diode electrode is different form that of the FET gate electrode, the noise characteristic of the diode in the low frequency band and the heat-resisting property of the FET can be simultaneously improved in the same chip.

### FIELD OF THE INVENTION

The invention relates to a semiconductor device and a method for fabricating the same, and especially to a semiconductor device in which a diode/FET electrode, a diode electrode and FET gate electrode are arranged forming a line, and a method for fabricating the same.

A monolithic microwave integrated circuit (a MMIC, hereinafter) is composed of FETs and diodes. An composite epitaxial layer used in a fabrication process of a hetero-junction FET (a HJFET, hereinafter) or a metal semiconductor FET (a MESFET, hereinafter) is also used in the fabrication process of the MMIC. As shown in FIG. 1, an epitaxial substrate 101 is composed of a GaAs substrate layer 102 and a buffer/channel layer 103. A n⁺-GaAs layer 104 is formed on a top surface of the buffer/channel layer 103. An ohmic metal layer 105 and a source/drain/cathode electrode (a diode/FET electrode) 106 are successively formed on a top surface of the n⁺-GaAs layer 104. A FET gate electrode 107 and a diode anode electrode 108 are respectively formed on the top surface of the buffer/channel layer 103. A diode is formed in a conductive resign which is inserted between the source/drain/cathode electrode 106 and the diode anode electrode 108, and includes a higher art the epitaxial substrate 101. Moreover, a FET is composed by the source/drain/cathode electrode 106, the FET gate electrode 107 and the other source/drain/cathode electrode (not shown) which is adjacent to the FET gate electrode 107 on the right side. As mentioned in the above, the source/drain/cathode electrode 106 serves as a cathode electrode of the diode in combination with the diode anode electrode 108, and as a source or drain electrode of the FET in combination with the FET gate electrode 107.

The conventional fabrication process of the diode/FET structure mentioned in the above comprises the step of forming the FET gate electrode 107 and the diode anode electrode 108 simultaneously and in the same structure. In the aforementioned step, the FET gate electrode 107 and the diode anode electrode 108 are simultaneously formed by WSi-spattering. The step of simultaneously forming the FET gate electrode 107 and the diode anode electrode 108 damages a region A shown in FIG. 1. The region A serves as the conductive region which is formed between the source/drain/cathode electrode 106 and the diode anode electrode 108, and includes the higher part of the epitaxial substrate 101. The conductive region A formed in this way is apt to be affected by surface state levels. Moreover, since the conductive region A is damaged in the steps of dry etching and spattering, the noise characteristic of the diode including the region A in the low frequency band is deteriorated. If the FET gate electrode 107 and the diode anode electrode 108 are simultaneously formed by evaporation (TiAl-evaporation, for instance) without using spattering, although the noise characteristic of the diode in the low frequency band is improved, the reliability of the FET in the heat-resisting property is lowered.

As mentioned in the above, it is earnestly desired that the reliability of the FET in the heat-resisting property and the noise characteristic of the diode in the low frequency band are simultaneously improved.

### SUMMARY OF THE INVENTION

Accordingly, it is an object of the invention to provide a semiconductor device in which the reliability of the FET in the heat-resisting property an the noise characteristic of the diode in the low frequency band are simultaneously improved, and a method for fabricating the same.

Next, means for settling the aforementioned problems will be explained. A bracket is added to each of technical items in the following descriptions, and a numeral or a notation is written in the bracket. The numeral or the notation used in the following description agrees with that used in the appended drawing for explaining the embodiment. That is to say, the numeral or the notation clarifies the correspondence or the mediation between the technical item written in the following description and the corresponding structural element shown in the drawing. However, the correspondence or the mediation mentioned in the above never means that interpretation of the technical item in the claim is restricted to that expressed by the drawings.

According to the first feature of the invention, a semiconductor device comprises:

an epitaxial substrate (1),

a first GaAs layer (4) formed on a top surface of the epitaxial substrate (1),

a first diode electrode (8) which is formed by evaporation on a top surface of the first GaAs layer (4),

a FET gate electrode (5) which is formed by spattering on the top surface of the epitaxial substrate (1), and

a diode/FET electrode (9) which is formed on a top surface of the first GaAs layer (4), and situated between the first diode electrode (8) and the FET gate electrode (5),

wherein the diode/FET electrode (9) serves as the second diode electrode in combination with the first diode electrode (8), and as a source or drain electrode in combination with the FET gate electrode (5).

As mentioned in the above, since the physical property of the first diode electrode (8) is different from that of the FET gate electrode (5) because of the difference in the way of forming therebetween, the reliability of the FET in the heat-resisting property is improved, and the noise characteristic of the diode in the low frequency band is also improved because of reduction of damage of the Schottky boundary surface.

Moreover, since the conductive region (B) of the diode, which is sharply affected by the surface state levels, is situated in a higher potion of the first GaAs layer (4), the conductive region (B) becomes hard to be affected by the surface state levels, so that the noise characteristic of the diode in the low frequency band is further improved.

The second GaAs layer (7) is additionally formed on the top surface of the first GaAs layer (4). That is to say, the second GaAs layer (7) is inserted between the first GaAs layer (4) and the first diode electrode (8). It is still more desirable to form the first diode electrode (8) on a top surface of the second GaAs layer (7) from the view point of the improving the noise characteristic of the diode.

It is desirable to insert an AlGaAs layer (6) between the first GaAs layer (4) and the second GaAs layer (7).

The diode/FET electrode is composed of an ohmic metal layer (9) formed on the top surface of the first GaAs layer (4) and a taking-out electrode (11) formed on the ohmic metal layer (9).

A right side surface of the second GaAs layer (7) is opposite to a left side surface of the ohmic metal layer (9), and a space formed therebetween is filled with insulating oxidation layers (13, 14).

As mentioned later, the AlGaAs layer (6) serves as a stoper layer in the step of etching the second GaAs layer (7).

A protective layer (15) is formed on outside surfaces of the insulating oxidation layers (13, 14) and the first diode electrode (8). The insulating oxidation layers (13, 14) are formed directly on the top surface of the first GaAs layer (4). In this case, it is desirable that the protective layer (15) is formed of nitride.

The epitaxial substrate (1) is composed of a GaAs substrate layer (2) and a channel layer (3) formed on a top surface of the GaAs substrate layer (2).

According to the second feature of the invention, a semiconductor device comprises:

an epitaxial substrate (1) which is composed of a GaAs substrate (2) and a channel layer (3) formed on a top surface of the GaAs substrate (2),

the first GaAs layer (4) which is formed on a top surface of the channel layer (3),

a double layer which is composed of an AlGaAs layer(6) and a second GaAs layer (7) formed thereon, and partially covers a top surface of the first Gays layer (4),

a FET gate electrode (5) which is formed by spattering on the top surface of the channel layer (3), which is exposed by a wide recess (26) formed on the first Gads layer (4),

the first diode electrode (8) which is formed by evaporation on a top surface of the second GaAs layer (7), and

a diode/FET electrode (9), which is formed on the top surface of the first GaAs layer (4), and situated between the first diode electrode (8) and the FET gate electrode (5),

wherein the diode/FET electrode (9) serves as the second diode electrode in combination with the first diode electrode (8), and as a source or drain electrode in combination with the FET gate electrode (5).

According to the third feature of the invention, a method for fabricating a semiconductor device, in which a FET gate electrode (5), a diode electrode (8) and a diode/FET electrode (9) are formed on the same chip, and the diode/FET electrode (9) serves as another diode electrode in combination with the diode electrode (8), and as a source or drain electrode in combination with the FET gate electrode (5), comprises the steps of:

forming an epitaxial substrate (1),

forming the first Gays layer (4) on a top surface of the epitaxial substrate (1),

forming the FET gate electrode (5) on the top surface of the epitaxial substrate (1),

forming the diode electrode (8) on a top surface of the fist GaAs layer (4), and

forming the diode/FET electrode (9) on the top surface of the first GaAs layer (4) and between the diode electrode (8) and the FET gate electrode (5).

The FET gate (5) is formed by spattering, and the diode electrode (8) is formed by evaporation.

The step of forming the epitaxial substrate (1) comprises the steps of:

forming a GaAs substrate (2), and

forming a channel layer (3) on a top surface of the GaAs substrate (2).

The step of forming the FET gate electrode (5) comprises the steps of:

forming a wide recess (26) on the first GaAs layer (4) by etching, and

forming the FET gate electrode (5) on the top surface of the epitaxial substrate (1) which is exposed on the wide recess (26).

The step of forming the diode electrode (8) further comprises the steps of:

forming the second GaAs layer (7) on the top surface of the first GaAs layer (4),

partially removing the second GaAs layer (7) by etching, and

forming one or more oxidation layers (13, 14) on outside surfaces of the diode/FET electrode (9), the FET gate electrode (5) and the second GaAs layer (7).

The step of forming the diode (8) comprises the steps of:

partially removing the oxidation layers (13, 14) by etching, and

forming the diode electrode (8) on the top surface of the second GaAs layer (7).

The step of forming the Diode/FET electrode (9) further comprises the steps of:

forming a protective layer (15) on outside surfaces of the diode electrode (8), the diode/FET electrode (9), and the FET gate electrode (5),

partially removing the protective layer (15) by etching, and

forming a taking-out electrode (11) on a top surface of the diode/FET electrode (9).

The step of forming the diode electrode (8) further comprises the steps of:

forming an AlGaAs layer on the top surface of the first GaAs layer (4),

wherein the step of forming the second GaAs layer (7) comprises the steps of:

partially removing the AlGas layer by etching, and

forming second GaAs layer (7) on a top surface the AlGaAs layer,

wherein the AlGaAs layer (6) serves as a stopper layer in the step of partially etching the second GaAs layer (7).

A method for fabricating a semiconductor device, in which a FET gate electrode (5), a diode electrode (8) and a diode/FET electrode (9) are formed on the same chip, and the diode/FET electrode (9) serves as another diode electrode in combination with the diode electrode (8), and as a source or drain electrode in combination with the FET gate electrode (5), comprising the steps of:

forming a channel layer (3) on a top surface of a GaAs substrate (2),

forming the first GaAs layer (4) on a top surface of the channel layer (3),

forming an AlGaAs layer (6) on a top surface of the first GaAs layer (4),

forming the second GaAs layer (7) on a top surface of the AlGaAs layer (6),

removing the second GaAs layer (7) and the AlGaAs layer(6) by etching except a predetermined region extending from a specified end of a composite layer formed by the above steps,

forming a wide recess (26) on the first GaAs layer (4) and in the neighborhood of the side end, the opposite to the specified end,

forming the FET gate electrode (5) by spattering on the top surface of the channel layer (3) exposed on the wide recess (26),

forming the diode/FET electrode (9) on the top surface of the first GaAs layer (4) and between the FET gate electrode (5) and the second GaAs layer (7) remaining on the predetermined region, and

forming the diode electrode on a top surface of the second GaAs layer (7).

The method for fabricating a semiconductor device further comprises the steps of:

forming the first oxidation layer (13) over whole outside surfaces of the FET gate electrode (5), the wide recess (26), and the first and second GaAs layers (4,7), and

partially removing the first oxidation layer (13) by etching on the top surface of the first GaAs layer (4),

between the steps of forming the FET gate electrode (5) and forming the diode/FET electrode (9).

The method for fabricating a semiconductor device further comprises the steps of:

forming the second oxidation layer (14) over whole outside surfaces of the diode/FET electrode (9), the FET gate electrode (5), the wide recess (26), and the first and second GaAs layers (4, 7), and

partially removing the first and second oxidation layers (13, 14) by etching on the top surface of the second GaAs layer (7),

between the steps of forming the diode/FET electrode (9) and forming the diode electrode (8).

The method for fabricating a semiconductor device further comprises the steps of:

forming a protective layer (15) on whole outside surfaces of the diode electrode (8), the diode/FET electrode (9), the FET gate electrode (5), and the first and second GaAs layers (4,7).

partially removing the protective layer (15) by etching, and

forming a taking-out electrode (11) on a top surface of the diode/FET electrode (9).

### BRIEF DESCRIPTION OF DRAWINGS

The invention will be explained in more detail in conjunction with appended drawings, wherein:

FIG. 1 is a cross-sectional view for showing a conventional semiconductor device,

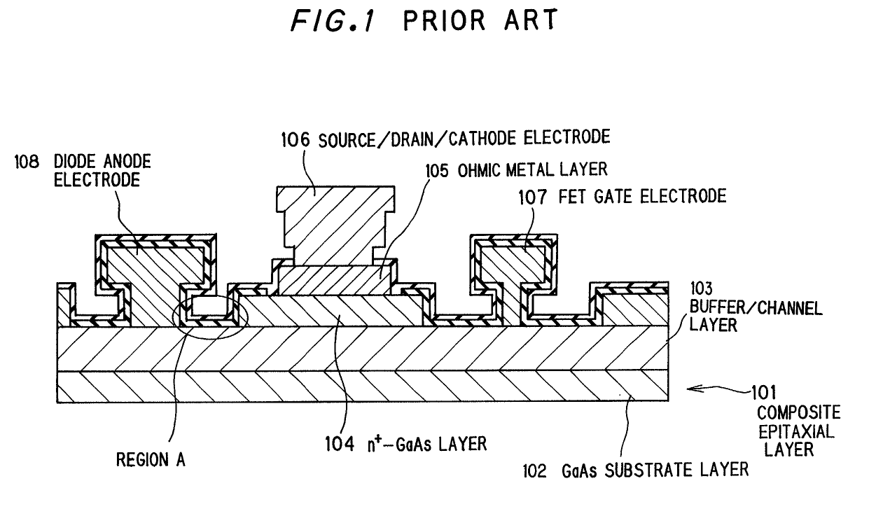

FIG. 2 is a cross-sectional view for showing a semiconductor device according to a preferred embodiment of the invention,

FIG. 3 is a cross-sectional view for showing an initial step of a process for fabricating a semiconductor device,

FIG. 4 is a cross-sectional view for a step of the fabrication process in which the greater part of the second GaAs layer and a stopper layer is removed.

FIG. 5 is a cross-sectional view for showing the next step of the fabrication process in which a wide recess is formed on the first GaAs layer.

FIG. 6 is a cross-sectional view for showing steps of the fabrication process in which a FET gate electrode and a diode/FET electrode are respecially formed,

FIG. 7 is a cross-sectional view for showing steps of the fabrication process in which the first and second oxidation layers are respectively formed on outside surfaces of the electrodes and the first and second GaAs layers,

FIG. 8 is a cross-sectional view for showing a step of the fabrication process in which a diode anode electrode is formed on a top surface of the second GaAs layer, and

FIG. 9 is a cross-sectional view for showing a state that a protective layer is formed on an outside surface of the semiconductor device.

### DESCRIPTION OF PREFERRED EMBODIMENTS

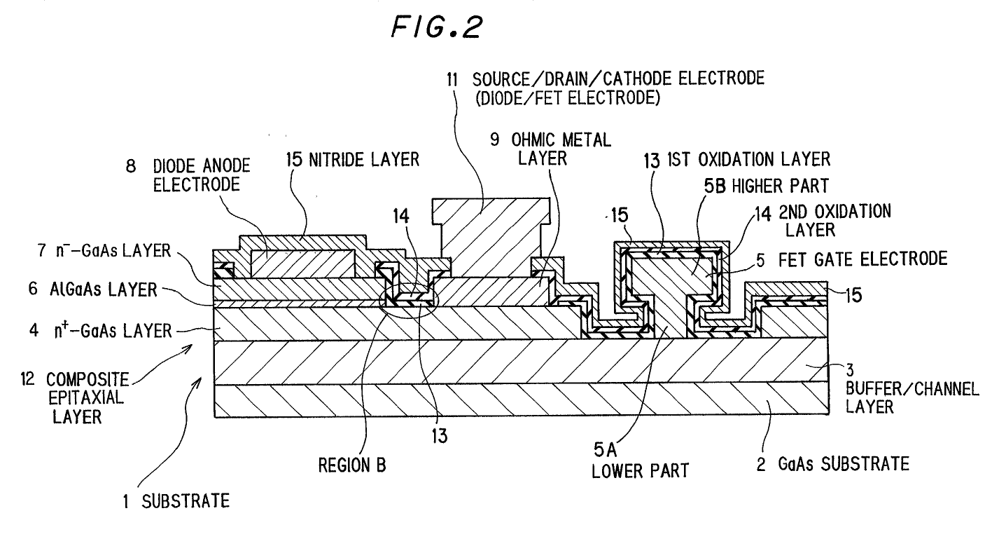

As shown in the appended drawings, a semiconductor device according to a preferred embodiment of the invention is composed of diodes and FETs formed on a top surface thereof. All the diodes and the FETs are formed independently of each other, and mounted of the same chip. FIG. 2 shows a part of the diodes and the FETs. The semiconductor device according to the embodiment of the invention is formed on an epitaxial substrate 1. The epitaxial substrate 1 is composed of a GaAs substrate 2 and a buffer/channel layer 3, which serves as both the buffer and channel layers. The buffer/channel layer 3 is formed on a top surface of the GaAs substrate 2.

A n⁺-GaAs layer 4 is formed on a top surface of a diode-forming region of the buffer/channel layer 3. A FET gate electrode 5 is formed on a top surface of a FET-forming region of the buffer/channel layer 3. Moreover, an AlGaAs layer 6 and a n⁻-GaAs layer 7 are successively formed on a top surface of the n⁺-GaAs layer 4. A diode anode electrode 8 is formed by evaporation on a top surface of the n⁻-GaAs layer 7. The diode anode electrode 8 can be formed by evaporation of TiAl. TiPtAu may be suitably used in stead of TiAl. An ohmic metal layer 9 and a source/drain/cathode electrode 11 are successively formed on the top surface of the n⁺-GaAs layer 4 and near the left end thereof. The source/drain/cathode electrode 11 serves a diode cathode electrode in combination with the diode anode electrode 8, and as a source or drain electrode in combination with the FET gate electrode 5. A composite epitaxial layer commonly used in the fabrication processes of the HJFET and the MESFET is composed of the GaAs substrate 2, the buffer/channel layer 3 which is formed on the top surface of the GaAs substrate 2, and the n⁺-GaAs layer 4 which is formed on the top surface of the buffer/channel layer 3.

As mentioned in the above, the aforementioned epitaxial substrate 1, the n⁺-GaAs layer 4, the AlGaAs layer 6, and the n⁻-GaAs layer 7 form a composite epitaxial layer 12, and the diode anode electrode 8 is formed on the top surface of the composite epitaxial layer 12. The FET gate electrode 5 is formed on the top surface of the epitaxial substrate 1. The right side surface of the n⁻-GaAs layer 7 is opposite to and remote from the left side surface of the ohmic metal layer 9, and a space formed therebetween is filled with the first and second oxidation layers 13, 14, each serving as an insulator. The right side surfaces of the n⁻-GaAs layer 7 and the diode anode electrode 8 are opposite to and remote from the left side surfaces of the ohmic metal layer 9 and the source/drain/cathode electrode (the cathode electrode in this case) 11, and a space formed therebetween is filled with the first and second oxidation layers 13, 14 and a nitride layer 15, each serving as an insulator. In the fabrication process of the semiconductor device according to the invention, the top and side surfaces of the first oxidation layer 13 are covered with the second oxidation layer 14, and the top and side surfaces of the second oxidation layer 14 are covered with the nitride layer 15.

The FET gate electrode 5 is composed of a lower part 5A having a narrower lateral width, and a higher part 5B having a wider lateral width. The side surfaces of the lower part 5A are successively covered with the first and second oxidation layers 13, 14 and the nitride layer 15. The top, bottom and side surfaces of the higher part 5B are successively covered with the fist and second oxidation layers 13, 14 and the nitride layer 15. The right side surfaces of the ohmic metal layer 9 and the n⁺-GaAs layer 4 are opposite to and remote from the left side surface of the FET gate electrode 5, and a space formed therebetween is filled with the first and second oxidation layers 13, 14 and the nitride layer 15, each serving as an insulator. The top surfaces of the diode anode electrode 8 and the n⁻-GaAs layer 7 are respectively covered with the nitride layer 15.

It is desirable that the thickness of the AlGaAs layer 6 is 50 to 100 Å. Moreover, it is important that the thickness of the n⁻-GaAs layer 7 is more than 1000 Å, and carrier concentration thereof is 0.5 to 6.0 E17/cm². The FET gate electrode 5 and the diode anode electrode 8 are respectively formed in the different steps. The FET gate electrode 5 is formed by the well-known spattering process, and completed as the spattered metal Schottky gate electrode. On the other hand, it is important that the diode anode electrode 8 is formed by a metal evaporation process, and not by the spattering process. The FET gate electrode 5 serving as a part of the FET is formed by spattering, so that the high reliability of the FET in the heat-resisting property can be assured similarly to the conventional device.

Since the diode anode electrode 8 serving as a part of the diode is formed by evaporation, the noise characteristic of the diode in the low frequency band is improved as compared with that of the conventional semiconductor device. Moreover, the diode anode electrode 8 serving as a part of the diode is formed on the top surface of the n⁻-GaAs layer 7, and a region which is apt to be affected by the surface state levels is illustrated as the region B in FIG. 2. The region B is inserted between the right side surface of the n⁻-GaAs layer 7 and the left side surface of the ohmic metal layer 9, which is situated under the source/drain/cathode electrode 11. Since the region B is formed in a higher part of the n⁺-GaAs layer 4 in which the carrier concentration is high; the region B is hard to be affected by the surface state levels, and the noise characteristic of the diode including the region B in the low frequency band can be further improved.

Moreover, since the carrier concentration in the n⁻-GaAs layer 7 is not so high, the diode anode electrode 8 and the n⁻-GaAs layer form a Schottky barrier diode, and the current in the n⁻-GaAs layer 7 flows almost vertically, so that the noise characteristic of the diode in the low frequency band is further improved.

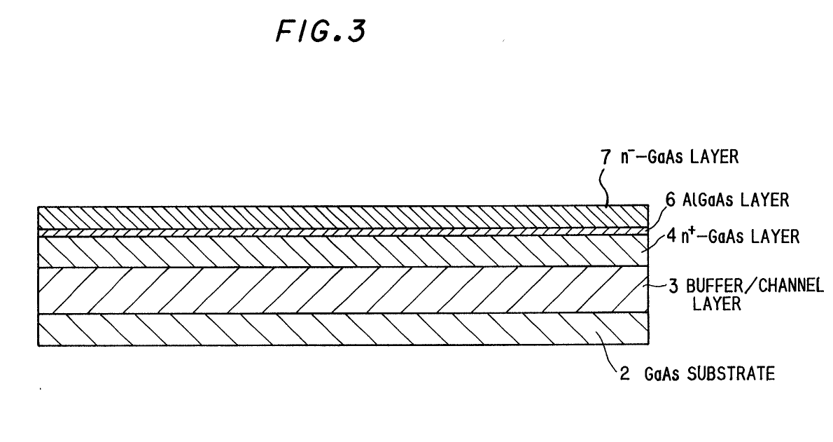

FIGS. 3 to 9 show a method for fabricating the semiconductor device shown in FIG. 2. As shown in FIG. 3, the buffer/channel layer 3 is formed on the top surface of the GaAs substrate 2, the n⁺-GaAs layer 4 is formed on the top surface of the buffer/channel layer 3, the AlGaAs layer 6 is formed on the top surface of the n⁺-GaAs layer 4, and the n⁻-GaAs layer 7 is formed on the top surface of the AlGaAs layer 6. As mentioned in the above, the AlGaAs layer 6 with a thickness of 50 to 100 Å is formed on the top surface of the composite epitaxial layer composed of the GaAs substrate 2, the buffer/channel layer 3 and the n⁺-GaAs layer 4, which is usually used in the fabrication process of the HJFET or the MESFET.

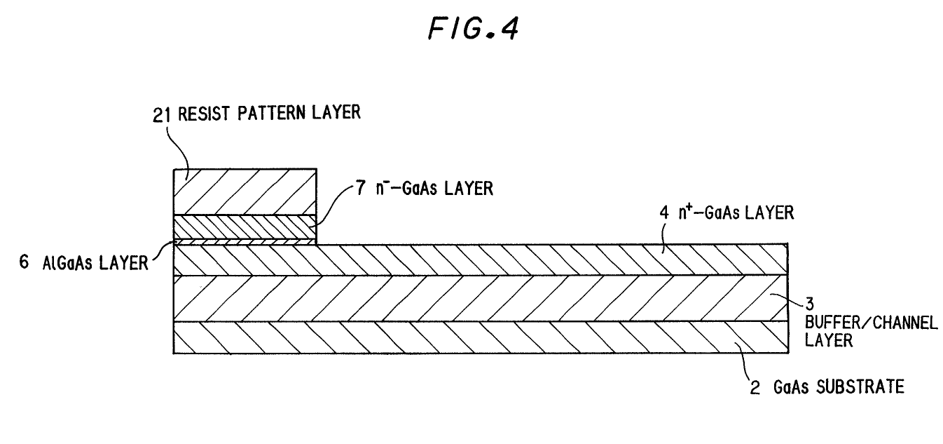

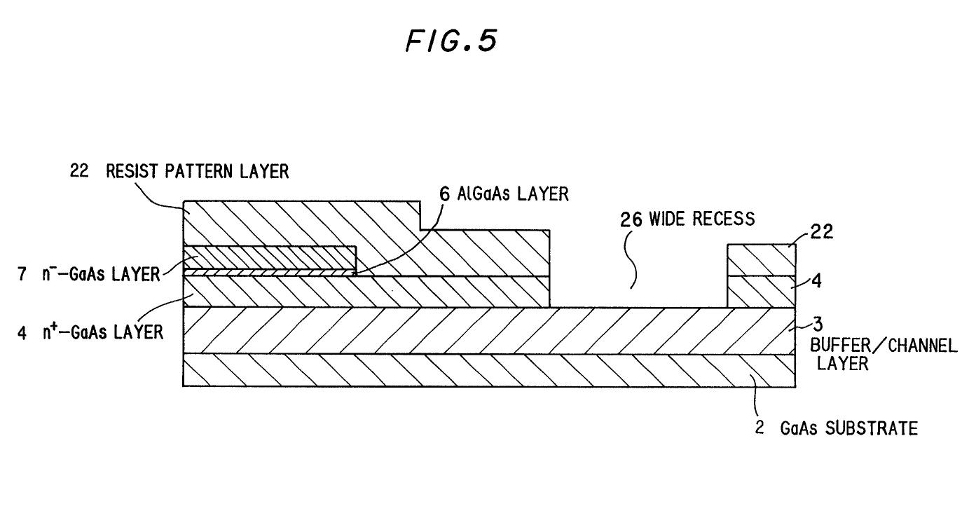

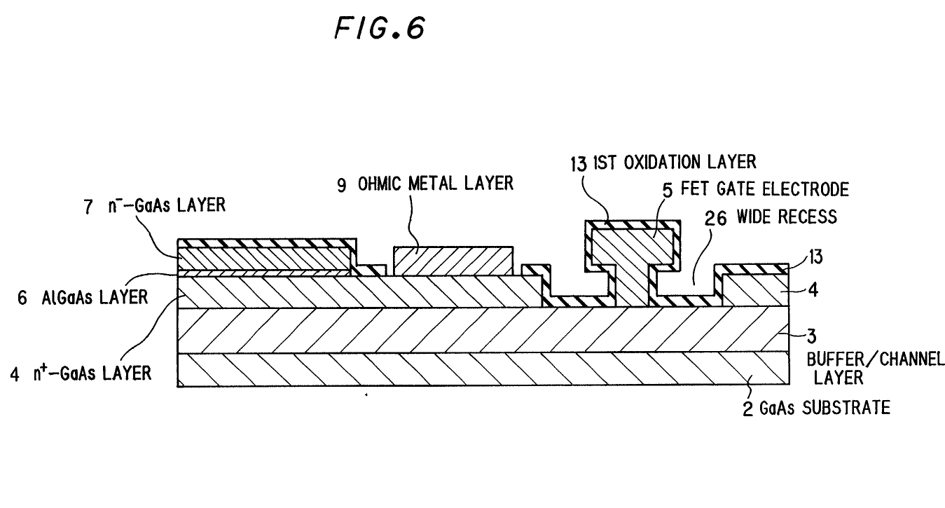

As shown in FIG. 4, a resist pattern 21 is formed on a top surface of the n⁻-GaAs layer 7, and the n⁻-GaAs layer 7, the highest layer, is etched by the crystal dry etching process. The AlGaAs layer 6, which has served as a stopper layer, is removed by the above step. Next, as shown in FIG. 5, a resist pattern 22 is formed on the top surfaces of the n⁺-GaAs layer 4 and the n⁻-GaAs layer 7. Then, a wide recess 26 is formed on the top surface of the buffer/channel layer 3 by crystal dry etching the n⁺-GaAs layer 4. As shown in FIG. 6, a FET gate electrode 5 with a spattered metal structure is formed on the top surface of the buffer/channel layer 3, which is exposed by the wide recess 26.

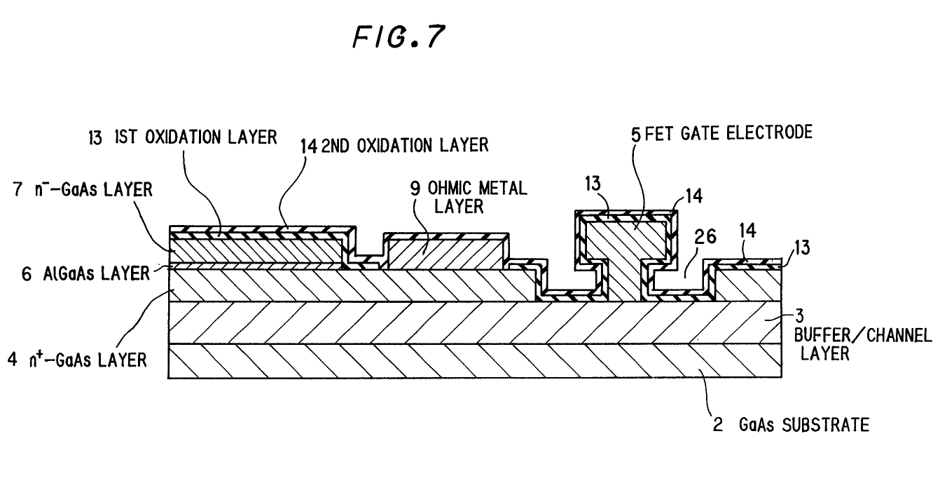

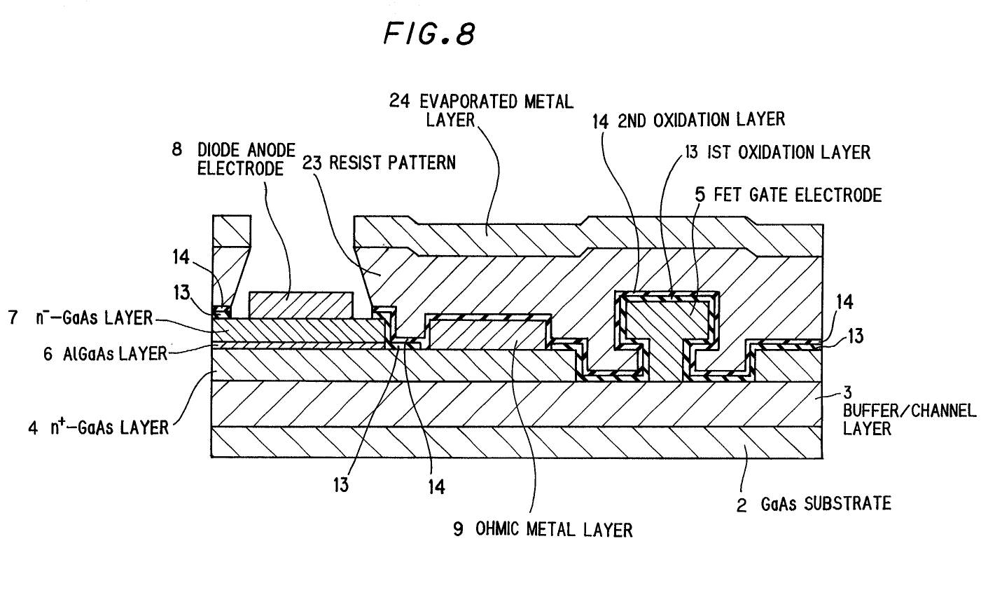

The first oxidation layer 13 for protecting the FET gate electrode 5 is formed on the whole surface of the semiprocessed product including outside surfaces of the FET gate electrode 5. After the first oxidation layer 13 is partially removed, the ohmic metal layer 9 is formed by the evaporation liftoff process on the exposed portion of the top surface of the n⁺-GaAs layer 4. Thereafter, the second oxidation layer 14 for protecting the ohmic metal layer 9 is formed over the whole surface of the semiprocessed product, as shown in FIG. 7. Next, as shown in FIG. 8, a resist pattern 23 is formed over the outside surface of the second oxidation layer 14, and, after the first and second oxidation layers 13, 14 are partially removed by etching on the top surface of the n⁻-GaAs layer 7, an evaporation metal layer is formed thereon using TiAl. Subsequently, the diode anode electrode 8 is formed by the liftoff process. In this step, a evaporation metal layer 24 is also formed on the outside surface of the resist pattern 23.

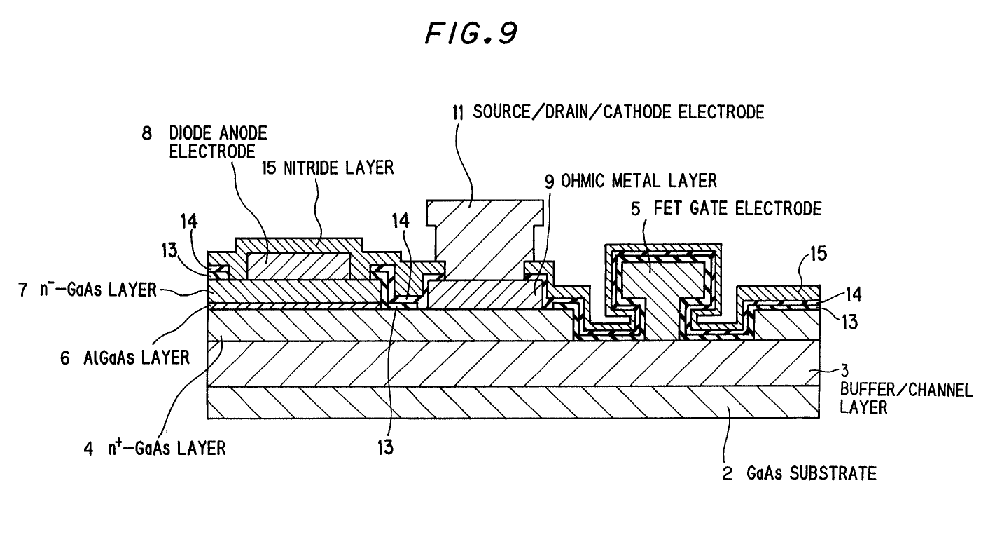

Next, as shown in FIG. 9, the resist pattern 23 and the evaporation metal layer 24 are removed, and the nitride layer 15 is formed over the whole surface of the semiprocessed product in order protect the diode anode electrode 8. Next, after a part of the nitride layer 15 formed on the ohmic metal layer 9 is removed, the source/drain/cathode electrode 11 is formed on the top surface of the ohmic metal layer 9. The other source/drain/cathode electrode (not shown) is formed beyond the FET gate electrode 5. The source/drain/cathode electrode 11 serves as a diode cathode electrode in combination with the diode anode electrode 8, and as a FET source or drain electrode in combination with the FET gate electrode 5.

The diode anode electrode 8 and the source/drain/cathode electrode 11 are used as a pair of electrodes forming the diode. The source/drain/cathode electrode 11, the FET gate electrode 5 and the other electrode (not shown) form a FET. The structure of the other electrode (not shown) is the same as that of the source/drain/cathode electrode 11 shown in FIG. 2. The plural diode anode electrodes 8, the plural source/drain/cathode electrodes 11, and the plural FET gate electrodes 5 are patterned and arranged of the same chip, and the diodes and the FETs are integrated on the top surface of a single epitaxial substrate 1. The diodes and the FETs are simultaneously formed by a signal process comprising the aforementioned steps. The plural source/drain/cathode electrodes with the same structure serve as the source, drain or diode electrodes (the diode cathode electrodes in the above drawings) depending on the structure of the neighboring electrodes.

As mentioned in the above, the AlGaAs layer and the n⁻-GaAs layer are successively formed on the composite epitaxial layer, which is usually used in the fabrication process on the HJFET or the MESFET, and the n⁻-GaAs layer is removed by the crystal dry etching process except a predetermined region, so that the diode anode-forming region can be formed on the top surface of then⁺-GaAs layer. The AlGaAs layer fulfills the function of a stopper layer in the step of etching the n⁻-GaAs layer.

According to the semiconductor device and the method for fabricating the same according to the invention, the noise characteristic of the diode in the low frequency band and the reliability of the FET in the heat-resisting property can be simultaneously improved on the same chip. As a result, the fabrication cost of the semiconductor device can be reduced, and the physical properties of the same can be improved by the fabrication process in which the diodes and the FETs are formed on the same chip. The step of forming the FET gate electrode by spattering and the same of forming the diode anode electrode by evaporation are performed in a single through process. Although spattering and evaporation are respectively performed in the different steps, cost of the semiconductor device can be reduced if the fabrication process is singly coordinated.

What is claimed is:

1. A semiconductor device, comprising:
an epitaxial substrate,
a first GaAs layer formed on a top surface of said epitaxial substrate,
a first diode electrode which is formed by evaporation on a top surface of said first GaAs layer,
a FET gate electrode which is formed by spattering on said top surface of said epitaxial substrate, and
a diode/FET electrode which is formed on a top surface of said first GaAs layer, and situated between said first diode electrode and said FET gate electrode,
wherein said diode/FET electrode serves as a second diode electrode in combination with said first diode electrode, and as a source or drain electrode in combination with said FET gate electrode.

2. The semiconductor device as defined in claim 1, further comprising:
a second GaAs layer inserted between said first GaAs layer and said first diode electrode.

3. The semiconductor device as defined in claim 2, further comprising:;
an AlGaAs layer inserted between said first and second GaAs layers.

4. The semiconductor device as defined in claim 2, further comprising:
a taking-out electrode formed on a top surface of said diode/FET electrode.

5. The semiconductor device as defined in claim 1, wherein:
said epitaxial substrate is composed of:
a GaAs substrate, and
a channel layer formed on a top surface of said GaAs substrate.

6. The semiconductor device, comprising:
an epitaxial substrate which is composed of a GaAs substrate and a channel layer formed on a top surface of said GaAs substrate,
a first GaAs layer which is formed on a top surface of said channel layer,
a double layer which is composed of an AlGaAs layer and a second GaAs layer formed thereon, and partially covers a top surface of said first GaAs layer,
a FET gate electrode which is formed by spattering on said top surface of said channel layer, which is exposed by a wide recess formed on said first GaAs layer,
a first diode electrode which is formed by evaporation on a top surface of said second GaAs layer, and
a diode/FET electrode, which is formed on said top surface of said first GaAs layer, and situated between said first diode electrode and said FET gate electrode,
wherein said diode/FET electrode serves as a second diode electrode in combination with said first diode electrode, and as a source or drain electrode in combination with said FET gate electrode.

7. A method for fabricating a semiconductor device, in which a FET gate electrode, a diode electrode and a diode/FET electrode are formed on a same chip, and said diode/FET electrode serves as another diode electrode in combination with said diode electrode, and as a source or drain electrode in combination with said FET gate electrode, comprising the steps of:
forming an epitaxial substrate,
forming a first GaAs layer on a top surface of said epitaxial substrate,
forming said FET gate electrode on said top surface of said epitaxial substrate,
forming said diode electrode on a top surface of said fist GaAs layer, and
forming said diode/FET electrode on said top surface of said first GaAs layer and between said diode electrode and said FET gate electrode.

8. The method for fabricating a semiconductor device as defined in claim 7, wherein:
said FET gate electrode is formed by spattering in said step of forming said FET gate electrode, and
said diode electrode is formed by evaporation in said step of forming said diode electrode.

9. The method for fabricating a semiconductor device as defined in claim 8, wherein:
said step of forming said epitaxial substrate comprises the steps of:
forming a GaAs substrate, and
forming a channel layer on a top surface of said GaAs substrate.

10. The method for fabricating a semiconductor device as defined in claim 8, wherein:
said step of forming said FET gate electrode comprises the steps of:
forming a wide recess on said first GaAs layer by etching, and
forming said FET gate electrode on said top surface of said epitaxial substrate which is exposed on said wide recess.

11. The method for fabricating a semiconductor device as defined in claim 8, further comprising the steps of:
forming a second GaAs layer on said top surface of said first GaAs layer,
partially removing said second GaAs layer by etching, and
forming one or more oxidation layers on outside surfaces of said diode/FET electrode, said FET gate electrode and said second GaAs layer.

12. The method for fabricating a semiconductor device as defined in claim 11, wherein:
said step of forming said diode electrode comprises the steps of:
partially removing said oxidation layers by etching, and
forming said diode electrode on said top surface of said second GaAs layer.

13. The method for fabricating a semiconductor device as defined in claim 12, further comprising the steps of:
forming a protective layer on outside surfaces of said diode electrode, said diode/FET electrode, and said FET gate electrode,
partially removing said protective layer by etching, and
forming a taking-out electrode on a top surface of said diode/FET electrode.

14. The method for fabricating a semiconductor device as defined in claim 8, further comprising the steps of:
forming a second GaAs layer on said top surface of said first GaAs layer, and
partially removing said second GaAs layer by etching, and
forming said diode electrode on a top surface of said second GaAs layer.

15. The method for fabricating a semiconductor device as defined in claim 14, further comprising the step of:
forming an AlGaAs layer on said top surface of said first GaAs layer,
wherein said step of forming said second GaAs layer comprises the steps of:
partially removing said AlGaAs layer by etching, and
forming said second GaAs layer on a top surface of said AlGaAs layer.

16. The method for fabricating a semiconductor device as defined in claim 13, further comprising the steps of:
forming an AlGaAs layer on said top surface of said first GaAs layer,
wherein said step of forming said second GaAs layer comprises the steps of:
partially removing said AlGaAs layer by etching, and
forming second GaAs layer on a top surface said AlGaAs layer,
wherein said AlGaAs layer serves as a stopper layer in said step of partially etching said second GaAs layer.

17. A method for fabricating a semiconductor device, in which a FET gate electrode, a diode electrode and a diode/FET electrode are formed on a same chip, and said diode/FET electrode serves as another diode electrode in combination with said diode electrode, and as a source or drain electrode in combination with said FET gate electrode, comprising the steps of:
forming a channel layer on a top surface of a GaAs substrate,
forming a first GaAs layer on a top surface of said channel layer,
forming an AlGaAs layer on a top surface of said first GaAs layer,
forming a second GaAs layer on a top surface of said AlGaAs layer,
removing said second GaAs layer and said AlGaAs layer by etching except a predetermined region extending from a specified end of a composite layer formed by said above steps,
forming a wide recess on said first GaAs layer and in a neighborhood of a side end, an opposite to said specified end,
forming said FET gate electrode by spattering on said top surface of said channel layer exposed on said wide recess,
forming said diode/FET electrode on said top surface of said first GaAs layer and between said FET gate electrode and said second GaAs layer remaining on said predetermined region, and
forming said diode electrode on a top surface of said second GaAs layer.

18. The method for fabricating a semiconductor device as defined in claim 17, further comprising the steps of:
forming a first oxidation layer over whole outside surfaces of said FET gate electrode, said wide recess, and said first and second GaAs layers, and
partially removing said first oxidation layer by etching on said top surface of said first GaAs layer,
between said steps of forming said FET gate electrode and forming said diode/FET electrode.

19. The method for fabricating a semiconductor device as defined in claim 18, further comprising the steps of:
forming a second oxidation layer over whole outside surfaces of said diode/FET electrode, said FET gate electrode, said wide recess, and said first and second GaAs layers, and
partially removing said first and second oxidation layers by etching on said top surface of said second GaAs layer,
between the steps of forming said diode/FET electrode and forming said diode electrode.

20. The method for fabricating a semiconductor device as defined in claim 19, further comprising the steps of:
forming a protective layer on whole outside surfaces of said diode electrode, said diode/FET electrode, said FET gate electrode, and said first and second GaAs layers.
partially removing said protective layer by etching, and
forming a taking-out electrode on a top surface of said diode/FET electrode.
